(19) United States
(12) Patent Application Publication
(10) Pub. No.: US 2012/0062256 A1
(43) Pub. Date: Mar. 15, 2012

(54) TEST APPARATUS, CALIBRATION METHOD AND RECORDING MEDIUM

(75) Inventor: Noriyoshi KOZUKA, Ibaraki (JP)

(73) Assignee: ADVANTEST CORPORATION, Tokyo (JP)

(21) Appl. No.: 13/267,890

(22) Filed: Oct. 7, 2011

Related U.S. Application Data
(63) Continuation of application No. PCT/JP2009/002996, filed on Jun. 29, 2009.

(51) Int. Cl. G01R 31/00; G01R 31/02

(52) U.S. Cl. 324/750.02; 324/537

(57) ABSTRACT

A test apparatus that tests a device under test, comprising first and second terminal groups including a plurality of drivers that output signals to the device under test; a first common setting section that sets a common delay amount for the signals output from one driver in the first terminal group and one driver in the second terminal group; and an inter-group adjusting section that causes reference phases of the signals output from the drivers in the first terminal group and reference phases of the signals output from the drivers in the second terminal group to draw near each other, based on a delay amount setting value set by the first common setting section when the reference phases in the first terminal group were adjusted and a delay amount setting value set by the first common setting section when the reference phases in the second terminal group were adjusted.

### BACKGROUND

1. TECHNICAL FIELD

The present invention relates to a test apparatus, a calibration method, and a recording medium on which a program is recorded.

2. Related Art

A test apparatus outputs a test signal having a designated waveform at a timing delayed from a reference phase by a designated amount, in each test cycle. The test apparatus also acquires the value of a response signal from the device under test at a timing delayed from a reference phase by a designated amount. The test apparatus includes many signal I/O sections that exchange signals with the device under test. The reference phases of the signal I/O sections are adjusted prior to testing to match each other, as shown in Patent Document 1, for example.

Patent Document 1: Japanese Patent No. 3565837

The signal I/O sections are divided among a plurality of substrates. A phase error in the reference phase between two signal I/O sections is usually greater for signal I/O sections on difference substrates than for signal I/O sections on the same substrate, due to conditions of the substrates such as the connection conditions of the connector.

Therefore, when the test apparatus causes the reference phases of the signal I/O sections to match, the signal I/O sections are divided into a plurality of groups, e.g. a group for each substrate. In this state, the test apparatus adjusts the reference phases of the signal I/O sections to be the same within each group, and then adjusts the reference phases of the signal I/O sections to be the same among all the groups. In this way, the test apparatus can efficiently cause the reference phases of a plurality of I/O sections to be the same.

When the adjustment is performed in two stages, the test apparatus must use a calibration board for adjusting the reference phases of the signal I/O sections within each group and a calibration board for adjusting the reference phases of the I/O sections among all of the groups. The calibration board for the intra-group adjustments may include wiring that causes a short between adjacent terminals in each group. The test apparatus uses such a calibration board to sequentially cause the reference phases between each pair of signal I/O sections connected to each other to match. In this way, the test apparatus can cause the reference phases of all the signal I/O sections within a group to be the same.

The calibration board for the inter-group adjustment includes wiring that causes a one-to-one short between terminals in different groups. The test apparatus uses such a calibration board and calculates the difference in reference phase between two signal I/O sections from different groups that are connected to each other. The test apparatus then shifts the reference phase of each signal I/O section in one of the groups by the average difference in reference phase between the pair. In this way, the test apparatus can cause the reference phases of the signal I/O sections in different groups to be the same.

However, when the adjustment is performed in two stages in this manner, at least two types of calibration boards must be mounted on the test apparatus to adjust the reference phases. Accordingly, the cost of the calibration boards increases and the time spent mounting the calibration boards also increases. As a result, the overall testing cost increases.

### SUMMARY

In order to solve the above problems, according to a first aspect related to the innovations herein, provided is a test apparatus that tests a device under test, comprising a first terminal group and a second terminal group including a plurality of drivers that output signals to the device under test; a first common setting section that sets a common delay amount for the signals output from one driver in the first terminal group and one driver in the second terminal group; and an inter-group adjusting section that causes reference phases of the signals output from the drivers in the first terminal group and reference phases of the signals output from the drivers in the second terminal group to draw near each other, based on a delay amount setting value set by the first common setting section when the reference phases in the first terminal group were adjusted and a delay amount setting value set by the first common setting section when the reference phases in the second terminal group were adjusted. Also provided is a calibration method for calibrating the test apparatus and a recording medium storing thereon a program for calibrating the test apparatus

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary hardware configuration of a test apparatus 10 according to an embodiment of the present invention, along with a device under test 300.

FIG. 2 shows an exemplary functional configuration of the test apparatus 10 according to the present embodiment during calibration.

FIG. 3 shows an exemplary configuration of an I/O section 30.

FIG. 4 shows exemplary configurations of two I/O sections 30 that output the same signal.

FIG. 5 shows a calibration process flow performed by the test apparatus 10 of the present embodiment.

FIG. 6 shows the flow of signals during the process of step S11.

FIG. 7 shows the flow of signals during the process of step S12.

FIG. 8 shows the flow of signals during the process of step S13.

FIG. 9 shows exemplary delay amount setting values for first to third terminal groups after the reference phases in each terminal group were adjusted, when the average delay amount setting value of the first terminal group is zero.

FIG. 10 shows exemplary delay amount setting values for the first terminal group, which uses the delay value setting amount of the fourth terminal group as a reference, together with the content of FIG. 9.

FIG. 11 shows an exemplary connection for a different process during step S12.

FIG. 12 shows an example of a hardware configuration of a computer 1900 according to the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

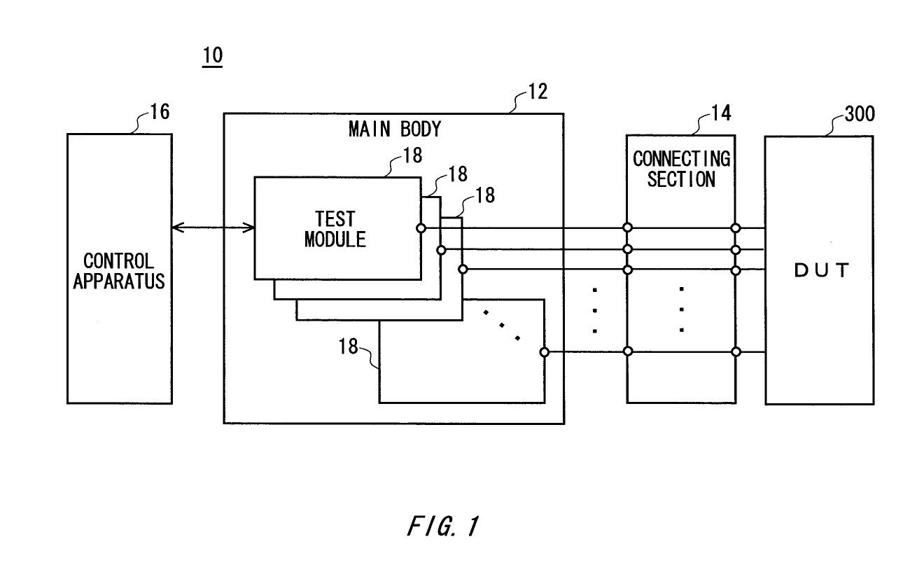

FIG. 1 shows an exemplary hardware configuration of a test apparatus 10 according to an embodiment of the present invention, along with a device under test 300. The test apparatus 10 of the present embodiment tests the device under test (DUT) 300. The test apparatus 10 includes a main body 12, a connecting section 14, and a control apparatus 16.

A plurality of test modules 18 are mounted in the main body 12. Each test module 18 executes a test program for test the device under test 300 by exchanging signals with the device under test 300.

More specifically, each test module 18 outputs a test signal having a designated waveform at a timing that is delayed by a designated time from a reference phase, in each test cycle. Furthermore, each test module 18 acquires a response signal from the device under test 300 at a timing delayed by a prescribed time from the reference phase.

The connecting section 14 is mounted in the main body 12. The device under test 300 is mounted on the connecting section 14, and the connecting section 14 provides a connection between the device under test 300 and the test modules 18. The connecting section 14 may be a board mounted on the main body 12, for example.

The control apparatus 16 controls the test modules 18 mounted in the main body 12, and causes the test modules 18 to test the device under test 300. Furthermore, the control apparatus 16 calibrates each of the test modules 18 prior to the testing. More specifically, during calibration, the control apparatus 16 causes each of the test modules 18 to have the same reference phase.

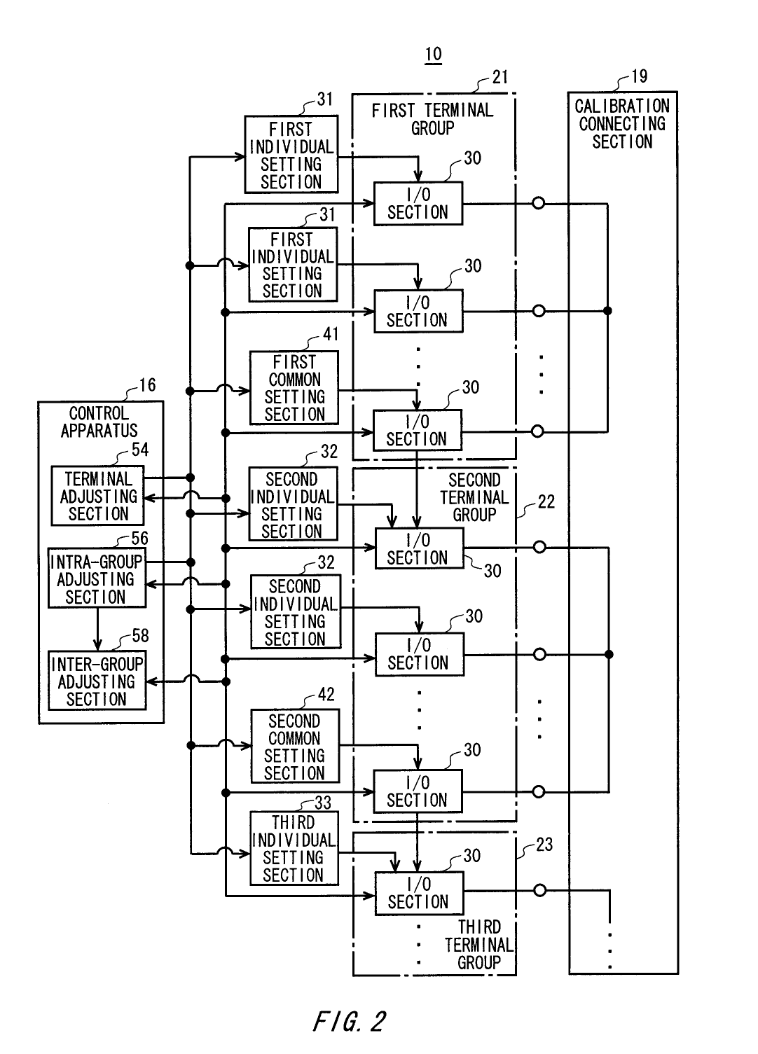

FIG. 2 shows an exemplary functional configuration of the test apparatus 10 according to the present embodiment during calibration. The test apparatus 10 includes a first terminal group 21, a second terminal group 22, a third terminal group 23, a plurality of first individual setting sections 31, a plurality of second individual setting sections 32, a plurality of third individual setting sections 33, at least one first common setting section 41, at least one second common setting section 42, a terminal adjusting section 54, an intra-group adjusting section 56, and an inter-group adjusting section 58.

The terminal adjusting section 54, the intra-group adjusting section 56, and the inter-group adjusting section 58 may be implemented in the control apparatus 16, for example. The other components may be implemented within the test modules 18 in the main body 12. During calibration, a calibration connecting section 19 is mounted on the main body 12 in place of the test modules 18.

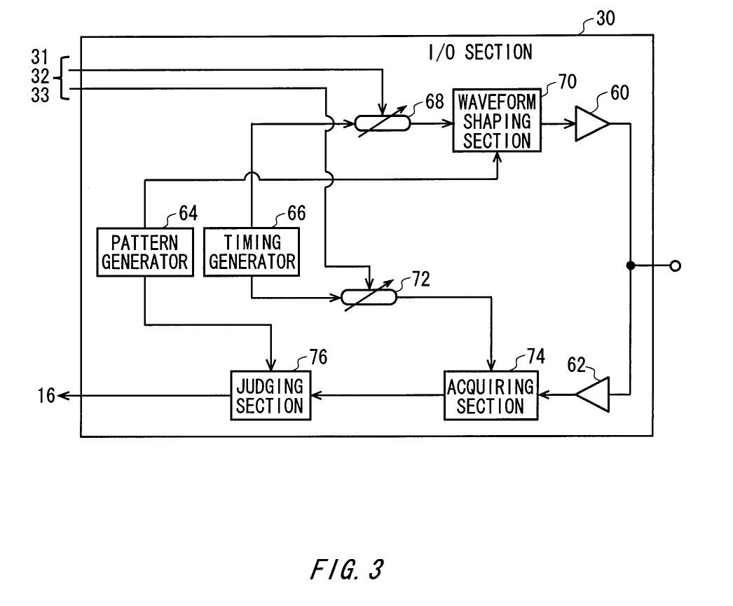

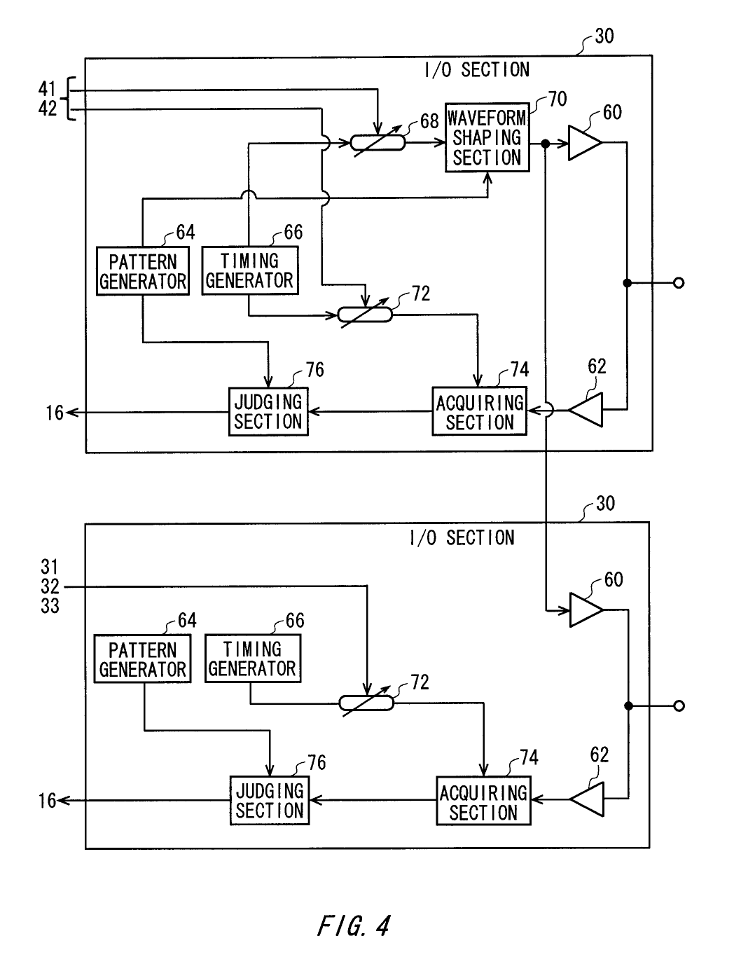

The first terminal group 21, the second terminal group 22, and the third terminal group 23 each include a plurality of I/O sections 30. Each I/O section 30 corresponds to a terminal of one or more devices under test 300. Each I/O section 30 includes a driver for outputting a signal to the corresponding terminal of the device under test 300 and a comparator for receiving a signal from the corresponding terminal. Each I/O section 30 exchanges signals with the corresponding terminal of the device under test 300 to test the device under test 300. An exemplary configuration of an I/O section 30 is described in FIGS. 3 and 4.

The first common setting section 41 is provided to correspond to one of the I/O sections 30 in the first terminal group 21. The first common setting section 41 sets the delay amount of the signal output from the driver of the one I/O section 30 in the first terminal group 21 and the delay amount of the timing at which the comparator of the one I/O section 30 in the first terminal group 21 receives a signal.

Here, the driver in the one I/O section 30 of the first terminal group 21 whose delay amount is adjusted by the first common setting section 41 outputs the same signal as the driver of one of the I/O sections 30 in the second terminal group 22. Accordingly, the first common setting section 41 sets a common delay amount for the signals output from the one driver in the first terminal group 21 and the one driver in the second terminal group 22.

For example, a common delay circuit may provide a signal to the one driver in the first terminal group 21 and the one driver in the second terminal group 22 for which the first common setting section 41 adjusts the delay amount. In this case, the first common setting section 41 sets the delay amount in the delay circuit that delays the signal supplied in common to the one driver in the first terminal group 21 and the one driver in the second terminal group 22.

The second common setting section 42 corresponds to one I/O section 30 in the second terminal group 22. The second common setting section 42 sets the delay amount of a signal output from the driver in the one I/O section 30 in the second terminal group 22 and the delay amount of the timing at which the comparator in one I/O section 30 in the second terminal group 22 receives a signal.

The driver in the one I/O section 30 in the second terminal group 22 for which the delay amount is adjusted by the second common setting section 42 outputs the same signal as the driver of one of the I/O sections 30 in the third terminal group 23. Accordingly, the second common setting section 42 sets a common delay amount for the signals output from the one driver in the second terminal group 22 and the one driver in the third terminal group 23.

For example, a common delay circuit may provide a signal to the one driver in the second terminal group 22 and the one driver in the third terminal group 23 for which the second common setting section 42 adjusts the delay amount. In this case, the second common setting section 42 sets the delay amount in the delay circuit that delays the signal supplied in common to the one driver in the second terminal group 22 and the one driver in the third terminal group 23.

As an example, if the test apparatus 10 tests a plurality of devices under test 300 in parallel, the first common setting section 41 and the second common setting section 42 correspond to a plurality of drivers that each provide the same signal, e.g. an address signal, to the devices under test 300.

Each first individual setting section 31 corresponds to one of the I/O sections 30 in the first terminal group 21, except for the one I/O section 30 corresponding to the first common setting section 41. Each second individual setting section 32 corresponds to one of the I/O sections 30 in the second terminal group 22, except for the one I/O section 30 corresponding to the second common setting section 42. Each third individual setting section 33 corresponds to an I/O section 30 in the third terminal group 23.

The first individual setting sections 31, the second individual setting sections 32, and the third individual setting sections 33 each set the delay amount of the signal output from the driver in the corresponding I/O section 30 and the delay amount of the timing at which a signal is input to the comparator in the corresponding I/O section 30. The second individual setting sections 32 and the third individual setting sections 33 each set the delay amount of only the timing at which a signal is input to the comparator if the delay amount of the driver in the corresponding I/O section 30 is set by the first common setting section 41 or the second common setting section 42.

The terminal adjusting section 54 causes the reference phase of the signal output from the driver in each I/O section 30 to draw near and match the reference phase of the timing at which a signal is input to the comparator of the I/O section 30.

The intra-group adjusting section 56 adjusts the delay amount set by each first individual setting section 31 and the first common setting section 41, such that reference phases of the signals output from the drivers in the first terminal group 21 draw near and match each other. Furthermore, the intra-group adjusting section 56 adjusts the delay amount set by each second individual setting section 32 and the first common setting section 41, such that reference phases of the signals output from the drivers in the second terminal group 22 draw near and match each other.

The inter-group adjusting section 58 causes the reference phases of the signals output from the drivers in the first terminal group 21 to draw near and match the reference phases of the signals output from the drivers in the second terminal group 22. Furthermore, the inter-group adjusting section 58 causes the reference phases of the signals output from the drivers in the second terminal group 22 to draw near and match the reference phases of the signals output from the drivers in the third terminal group 23.

The test apparatus 10 may include four or more terminal groups. In this case, each terminal group has the same function and configuration as the first terminal group 21 and the second terminal group 22.

Furthermore, when there are four or more terminal groups, the test apparatus 10 includes a plurality of individual setting sections and at least one common setting section corresponding to each terminal group. Each individual setting section has the same function and configuration as the first individual setting sections 31, the second individual setting sections 32, and the third individual setting sections 33. At least one common setting section has the same function and configuration as the first common setting section 41 and the second common setting section 42.

The terminal adjusting section 54 used when there are four or more terminal groups causes the reference phases of the signals output by the drivers in all of the I/O sections 30 in the terminal groups to draw near and match the reference phases of the timings at which the signals are input to the comparators. Furthermore, the intra-group adjusting section 56 causes the reference phases of the I/O sections 30 in each terminal group to draw near and match each other. The inter-group adjusting section 58 causes the reference phases of the I/O sections 30 to match between all of the terminal groups.

FIG. 3 shows an exemplary configuration of an I/O section 30. The I/O section 30 includes a driver 60, a comparator 62, a pattern generator 64, a timing generator 66, an output-side delay circuit 68, a waveform shaping section 70, an acquisition-side delay circuit 72, an acquiring section 74, and a judging section 76.

The driver 60 outputs, to the corresponding terminal of the device under test 300, a signal having a voltage level corresponding to a logic signal supplied from the waveform shaping section 70. The comparator 62 receives a signal from the corresponding terminal of the device under test 300, and generates a logic signal having a logic value corresponding to the voltage level of the received signal. The comparator 62 supplies the acquiring section 74 with the generated logic signal. The terminal from which the driver 60 outputs signals is the same as the terminal at which the comparator 62 receives signals.

The pattern generator 64 generates a logic pattern designating a waveform and a generation timing of the signal generated by the I/O section 30. Furthermore, the pattern generator 64 generates an expected value pattern designating an acquisition timing for acquiring the signal input to the I/O section 30 and an expected value of this signal. The pattern generator 64 supplies the generated logic pattern to the waveform shaping section 70 in each test cycle. Furthermore, the pattern generator 64 supplies the generated expected pattern to the judging section 76.

The timing generator 66 generates a timing signal designating a timing at which the I/O section 30 outputs a signal. Furthermore, the timing generator 66 generates a strobe signal designating a timing at which the value of a signal is received by the I/O section 30. For example, the timing generator 66 may generate a timing signal and a strobe signal for each test cycle. The timing generator 66 supplies the output-side delay circuit 68 with the timing signal and supplies the acquisition-side delay circuit 72 with the strobe signal.

The output-side delay circuit 68 delays the timing signal supplied from the timing generator 66 in each test cycle from the reference phase by a delay amount corresponding to the designated generation timing, and supplies the resulting timing signal to the waveform shaping section 70. Furthermore, the output-side delay circuit 68 receives a setting value for the delay amount from a first individual setting section 31, a second individual setting section 32, or a third individual setting section 33. The output-side delay circuit 68 sets the reference phase according to the received setting value.

The waveform shaping section 70 generates the logic signal of the waveform designated by the pattern generator 64, at the timing of the timing signal delayed by the output-side delay circuit 68. The waveform shaping section 70 supplies the generated logic signal to the driver 60.

The acquisition-side delay circuit 72 delays the strobe signal supplied from the timing generator 66 in each test cycle from a reference phase by a delay amount corresponding to the designated acquisition timing, and supplies the delayed strobe signal to the acquiring section 74. Furthermore, the acquisition-side delay circuit 72 receives a setting value for the delay amount from the first individual setting section 31, the second individual setting section 32, or the third individual setting section 33. The acquisition-side delay circuit 72 sets the reference phase according to the received setting value.

The acquiring section 74 acquires the logic value of the logic signal output from the comparator 62, at the timing of the strobe signal delayed by the acquisition-side delay circuit 72. The acquiring section 74 supplies the acquired logic value to the judging section 76.

The judging section 76 makes a comparison to determine if the logic value acquired by the acquiring section 74 matches the expected value designated by the pattern generator 64. The acquiring section 74 supplies the comparison result to the pattern generator 64, the control apparatus 16, or a memory that can be read by the control apparatus 16, for example.

FIG. 4 shows exemplary configurations of two I/O sections 30 that output the same signal. One of the I/O sections 30 in the second terminal group 22 outputs the same signal as one of the I/O sections 30 in the first terminal group 21. In this case, the one I/O section 30 in the second terminal group 22 does not include the output-side delay circuit 68 or the waveform shaping section 70.

Furthermore, in this case, the driver 60 in the one I/O section 30 in the second terminal group 22 receives a signal from the waveform shaping section 70 in the one I/O section 30 in the first terminal group 21. Accordingly, the first common setting section 41 can set the same delay amount for the signals output by the driver 60 in the one I/O section 30 in the first terminal group 21 and the driver 60 in the one I/O section 30 in the second terminal group 22.

Similarly, one of the I/O sections 30 in the third terminal group 23 outputs the same signal as one of the I/O sections 30 in the second terminal group 22. In this case, the one I/O section 30 in the third terminal group 23 does not include the output-side delay circuit 68 or the waveform shaping section 70.

Furthermore, in this case, the driver 60 in the one I/O section 30 in the third terminal group 23 receives a signal from the waveform shaping section 70 in the one I/O section 30 in the second terminal group 22. Accordingly, the second common setting section 42 can set the same delay amount for the signals output by the driver 60 in the one I/O section 30 in the second terminal group 22 and the driver 60 in the one I/O section 30 in the third terminal group 23.

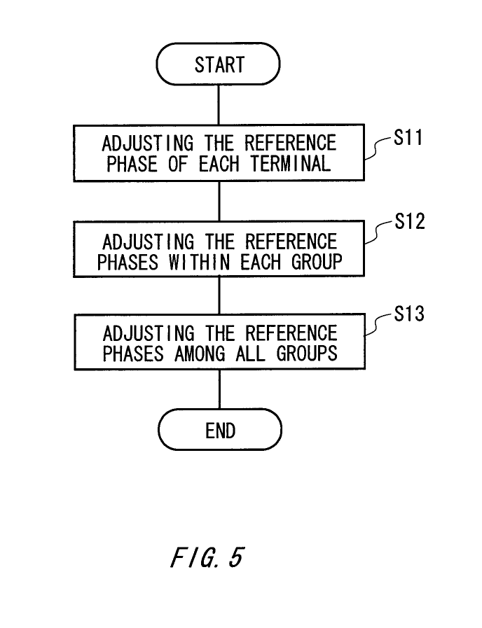

FIG. 5 shows a calibration process flow performed by the test apparatus 10 of the present embodiment. Prior to testing, the test apparatus 10 sequentially performs steps S11 to S13 of the calibration process described below.

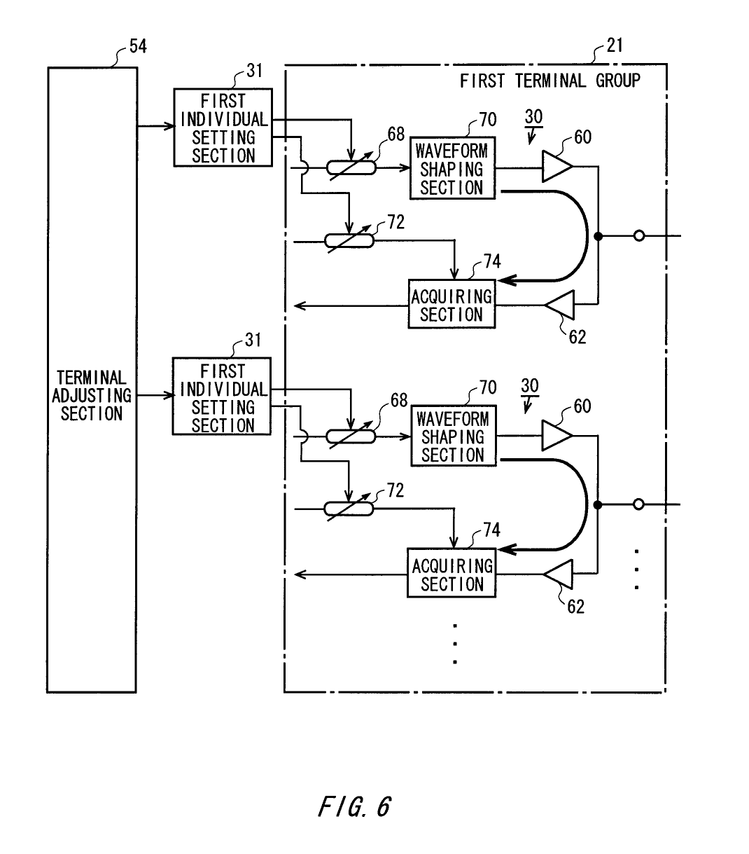

First, for each I/O section 30 of the test apparatus 10, the test apparatus 10 causes the reference phase of the signal output from the driver 60 to match the reference phase of the signal acquisition timing of the comparator 62 (S11). An example of the process performed at step S11 is described in relation to FIG. 6.

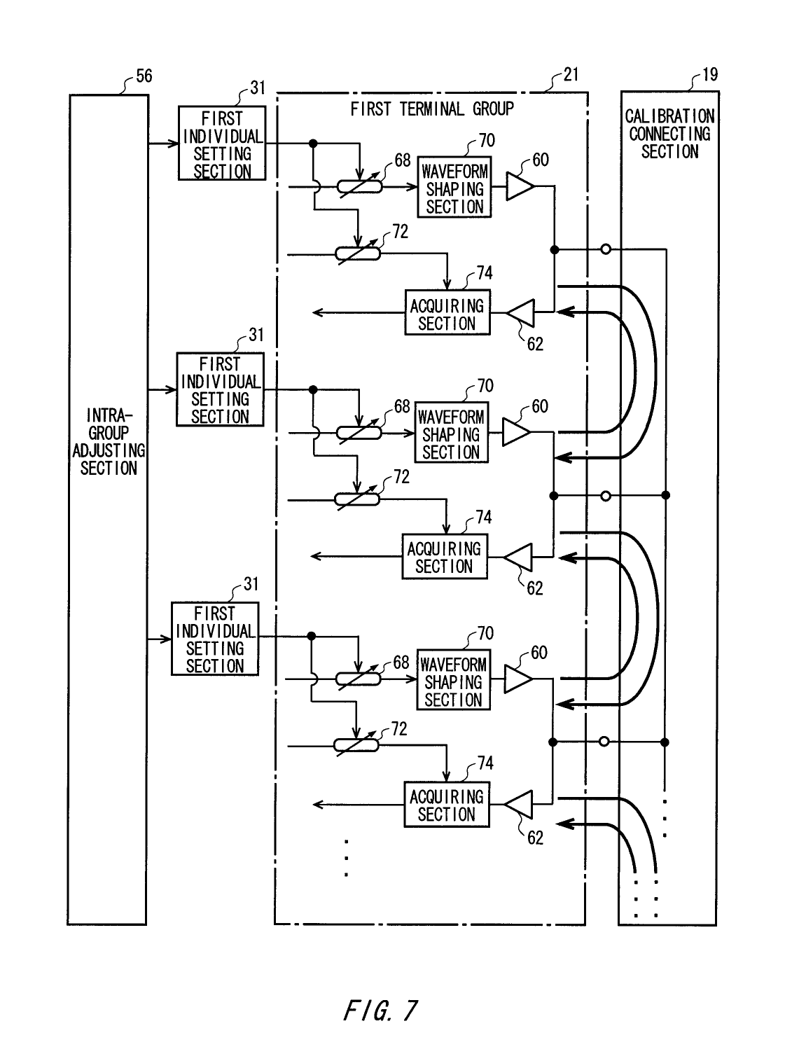

Next, for each terminal group, the test apparatus 10 causes the reference phases of the I/O sections 30 in the terminal group to be the same as each other (S12). An example of the process performed at step S12 is described in relation to FIG. 7.

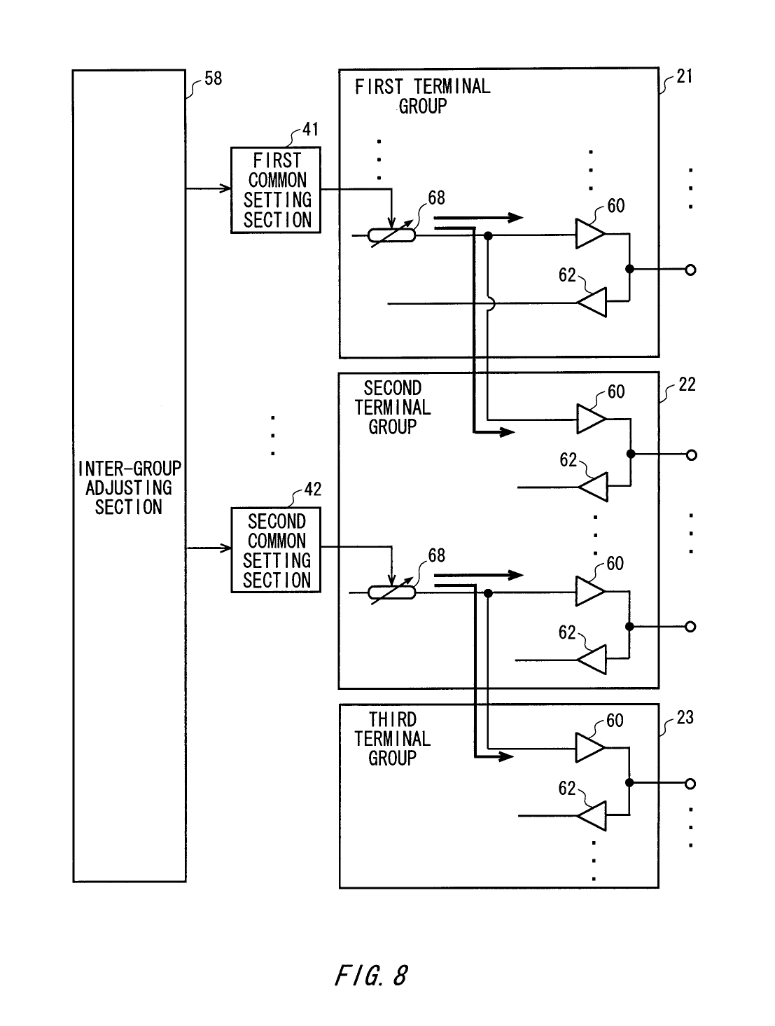

Next, the test apparatus 10 causes the reference phases of the I/O sections 30 to be the same amongst the terminal groups (S13). An example of the process performed at step S13 is described in relation to FIG. 8 and onward. By performing the above process, the test apparatus 10 can cause the reference phases of all of the I/O sections 30 in the test apparatus 10 to be the same.

FIG. 6 shows the flow of signals during the process of step S11. In step S11, the terminal adjusting section 54 performs the following process on each I/O section 30.

The terminal adjusting section 54 causes the driver 60 to output a signal with a prescribed waveform. The signal output from the driver 60 is looped back to the comparator 62 in the same I/O section 30. The terminal adjusting section 54 changes the delay amount setting value supplied to the output-side delay circuit 68 or the acquisition-side delay circuit 72, such that the output signal having the prescribed waveform is acquired by the acquiring section 74 at a time that is delayed by an amount equivalent to the wire delay.

In this way, for each I/O section 30, the terminal adjusting section 54 can cause the reference phase of the signal output from the driver 60 to match the reference phase of the signal acquired by the comparator 62. When performing the process of step S11, the terminal adjusting section 54 preferably opens the relay between the I/O sections 30 and the device under test 300.

FIG. 7 shows the flow of signals during the process of step S12. In step S12, the intra-group adjusting section 56 performs the following process on each terminal group. In this example, there is a first terminal group 21, a second terminal group 22, and a third terminal group 23.

First, a calibration connecting section 19 that creates a short between adjacent terminals in the terminal group is attached to the test apparatus 10. Next, the intra-group adjusting section 56 causes a first I/O section 30 in the terminal group to output a signal having a prescribed waveform, and changes the signal output timing or acquisition timing from an initial value such that the signal having the prescribed waveform output from the first I/O section 30 is acquired by a second I/O section 30.

Next, the intra-group adjusting section 56 causes the second I/O section 30 in the terminal group to output a signal having a prescribed waveform, and changes the signal output timing or acquisition timing from an initial value such that the signal having the prescribed waveform output from the second I/O section 30 is acquired by the first I/O section 30. The intra-group adjusting section 56 then calculates a value that is half of the difference between the amount by which the timing was changed from the initial value when causing the signal output by the first I/O section 30 to be acquired by the second I/O section 30 and the amount by which the timing was changed from the initial value when causing the signal output by the second I/O section 30 to be acquired by the first I/O section 30.

The intra-group adjusting section 56 then shifts the setting value for the delay amount supplied to the output-side delay circuit 68 or the acquisition-side delay circuit 72 in the second I/O section 30 by a delay amount corresponding to the calculation result. In this way, the intra-group adjusting section 56 can cause the reference phase of the first I/O section 30 and the reference phase of the second I/O section 30 to be the same.

Next, the intra-group adjusting section 56 performs the same process for the second and third I/O sections 30. The intra-group adjusting section 56 also performs this process for each pair of adjacent I/O sections 30 from the third I/O section 30 onward. In this way, the intra-group adjusting section 56 can cause the reference phases of the signals output from the drivers 60 in each terminal group to draw near and match each other. When performing the process of step S12, the intra-group adjusting section 56 preferably causes the I/O terminals of I/O sections 30 on which the process is not being performed to terminate.

FIG. 8 shows the flow of signals during the process of step S13. In step S13, the inter-group adjusting section 58 performs the following process.

First, the inter-group adjusting section 58 acquires the setting value of the delay amount set by the first common setting section 41 when the reference phases in the first terminal group 21 were adjusted. The inter-group adjusting section 58 then acquires the setting value of the delay amount set by the first common setting section 41 when the reference phases in the second terminal group 22 were adjusted.

Next, the inter-group adjusting section 58 calculates a difference value between the delay amount setting value set by the first common setting section 41 when the reference phases in the first terminal group 21 were adjusted and the delay amount setting value set by the first common setting section 41 when the reference phases in the second terminal group 22 were adjusted.

Next, the inter-group adjusting section 58 calculates a first shift amount corresponding to the calculated difference value. If there is one first common setting section 41, the inter-group adjusting section 58 may set the calculated difference value as the first shift amount. If the test apparatus 10 includes a plurality of first common setting sections 41, the inter-group adjusting section 58 may calculate the average of the difference values calculated for each first common setting section 41, and set this average as the first shift amount.

The inter-group adjusting section 58 shifts each delay amount setting value set for the second common setting section 42 and the second individual setting sections 32 by the calculated first shift amount. In this way, the inter-group adjusting section 58 can cause the reference phase of the signals output from the drivers 60 in the second terminal group 22 to draw near and match the reference phase of the signals output from the drivers 60 in the first terminal group 21.

Furthermore, the inter-group adjusting section 58 acquires the delay amount setting value set by the second common setting section 42 when the reference phases in the second terminal group 22 were adjusted. The inter-group adjusting section 58 then acquires the delay amount setting value set by the second common setting section 42 when the reference phases in the third terminal group 23 were adjusted.

Next, the inter-group adjusting section 58 calculates the difference value between the delay amount setting value set by the second common setting section 42 when the reference phases in the second terminal group 22 were adjusted and the delay amount setting value set by the second common setting section 42 when the reference phases in the third terminal group 23 were adjusted.

Next, the inter-group adjusting section 58 calculates a second shift amount corresponding to the calculated difference value. If there is one second common setting section 42, the inter-group adjusting section 58 may set the calculated difference value as the second shift amount. If the test apparatus 10 includes a plurality of second common setting sections 42, the inter-group adjusting section 58 may calculate the average of the difference values calculated for each second common setting section 42, and set this average as the second shift amount.

The inter-group adjusting section 58 then shifts the delay amount setting value set by each third individual setting section 33 by an amount equal to the sum of the first shift amount and the second shift amount. In this way, the inter-group adjusting section 58 can cause the reference phases of the signals output from the drivers 60 in the third terminal group 23 to draw near and match the reference phases of the signals output from the drivers 60 in the second terminal group 22.

In step S13, the inter-group adjusting section 58 may calculate the shift amounts of the terminal groups en masse. The inter-group adjusting section 58 may then shift the delay amount setting values of the I/O sections 30 in the terminal groups en masse.

The test apparatus 10 described above can adjust the reference phases among terminal groups without using a dedicated calibration connecting section for the adjustment, e.g. without using short boards corresponding one-to-one with the terminals in different groups. Therefore, the test apparatus 10 can lower testing cost by eliminating the cost of creating the dedicated calibration connecting section for adjustments between terminal groups, and also eliminates the effort involved in replacing the calibration connecting section.

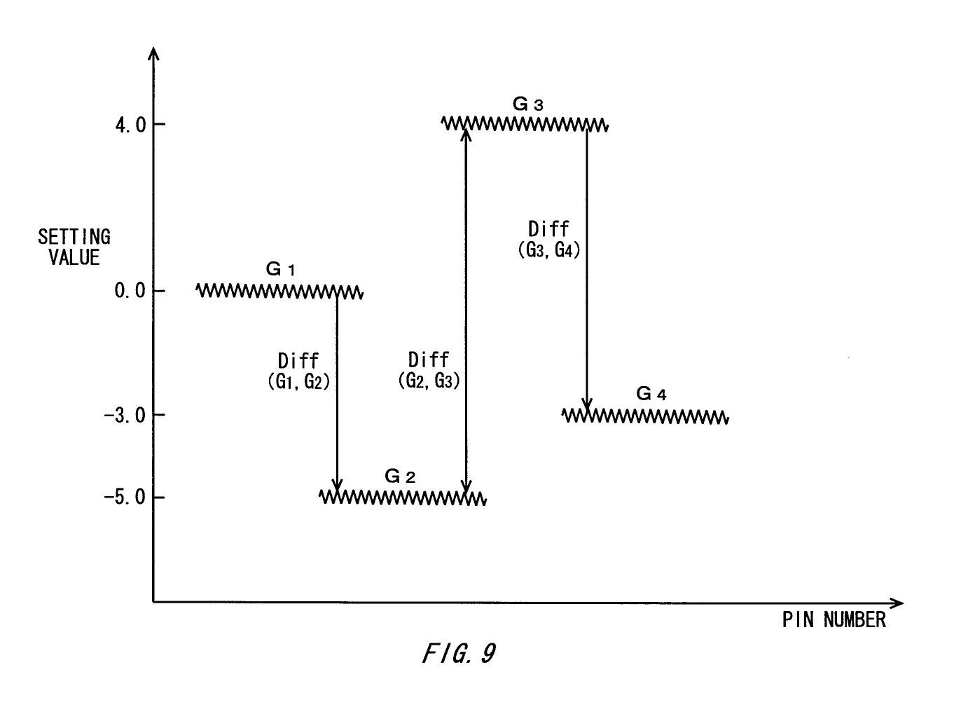

FIG. 9 shows exemplary delay amount setting values for first to fourth terminal groups after the reference phases in each terminal group have been adjusted, when the average delay amount setting value of the first terminal group is zero. Here, there are nₘₐₓ terminals that output the same output signals in the g-th terminal group and the (g+1)-th terminal group, where nₘₐₓ and g are positive integers.

The delay amount setting value of the common setting section for the n-th terminal in the g-th terminal group is expressed as CALDA(G_{g}, n), where n is a positive integer no greater than nₘₐₓ. The delay amount setting value of the common setting section for the n-th terminal in the (g+1)-th terminal group, which outputs the same output signal as the n-th terminal in the g-th terminal group, is expressed as CALDA(G_{g+1}, n).

In this case, the difference value (Diff(G_{g}, G_{g+1})) between the g-th terminal group and the (g+1)-th terminal group can be expressed by Expression 1 shown below. In other words, the difference value (Diff(G_{g}, G_{g+1})) is the average of values obtained by subtracting the delay amount setting values of the terminals in the g-th terminal group from the delay amount setting values of the terminals in the (g+1)-th terminal group, for each pair of terminals that output the same signal as each other.

$$\begin{matrix} Expression 1 & \\ Diff ( {G}_{g} , {G}_{g + 1} ) = \frac{1}{{n}_{ma x}} {\sum }_{n = 1}^{{n}_{ma x}} ( CALDA ( {G}_{g + 1} , n ) - CALDA ( {G}_{g} , n ) ) & ( 1 )\end{matrix}$$

The inter-group adjusting section 58 calculates the shift amount (ShiftTime(Gₕ)) as shown below in Expression 2 for the h-th terminal group, where h is an integer greater than 1 and no greater than the number (gₘₐₓ) of terminal groups. In other words, the inter-group adjusting section 58 calculates the shift amount (ShiftTime(Gₕ)) for the h-th terminal group by accumulating the difference values from the difference between the first and second terminal groups to the difference between the (h−1)-th and h-th terminal groups.

$$\begin{matrix}Expression 2 & \\ ShiftTime ( {G}_{h} ) = {\sum }_{g = 1}^{h - 1} Diff ( {G}_{g} , {G}_{g + 1} ) & ( 2 )\end{matrix}$$

The inter-group adjusting section 58 then shifts the delay amount setting value for each I/O section 30 in the h-th terminal group by the calculated shift amount (ShiftTime(Gₕ)). In this way, the inter-group adjusting section 58 can cause the reference phases of the I/O sections 30 in the terminal groups to be the same as each other.

In the example of FIG. 9, the difference value (Diff(G₁, G₂)) between the first terminal group and the second terminal group, the difference value (Diff(G₂, G₃)) between the second terminal group and the third terminal group, and the difference value (Diff(G₃, G₄)) between the third terminal group and the fourth terminal group are the values shown below.

Diff(G₁,G₂)=−5.0 ns

Diff(G₂,G₃)=9.0 ns

Diff(G₃,G₄)=−7.0 ns

Accordingly, in this case, the shift amount (ShiftTime(G₁)) for the first terminal group, the shift amount (ShiftTime(G₂)) for the second terminal group, the shift amount (ShiftTime(G₃)) for the third terminal group, and the shift amount (ShiftTime(G₄)) for the fourth terminal group are the values shown below.

ShiftTime(G₁)=0.0 ns

ShiftTime(G₂)=0.0−5.0=−5.0 ns

ShiftTime(G₃)=0.0−5.0+9.0=4.0 ns

ShiftTime(G₄)=0.0−5.0+9.0−7.0=−3.0 ns

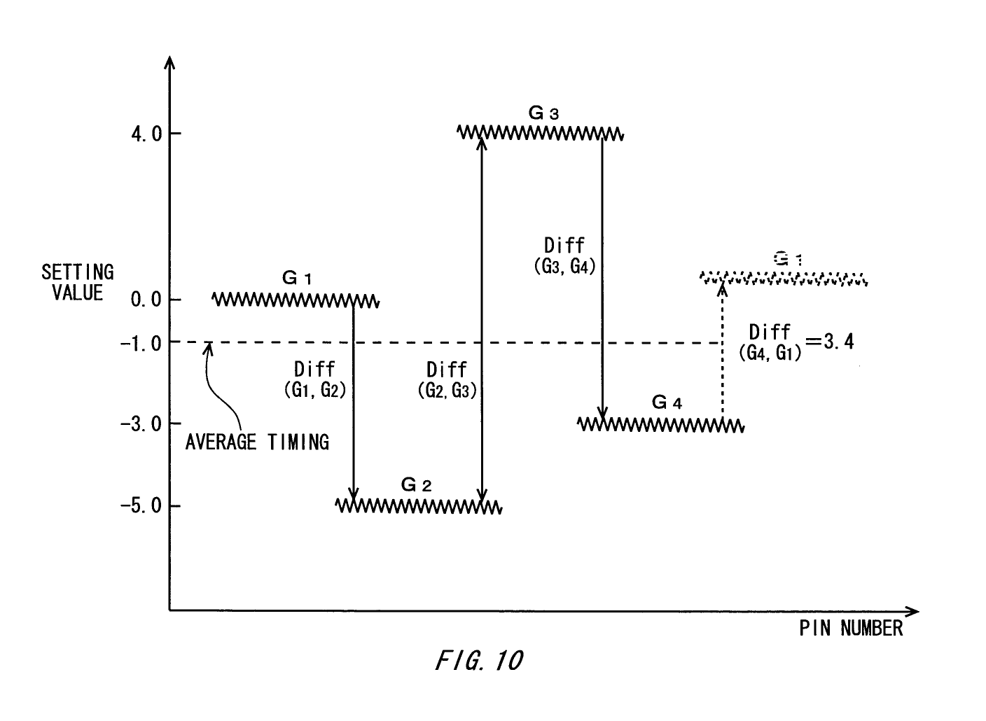

FIG. 10 shows exemplary delay amount setting values for the first terminal group, which uses the delay value setting amount of the fourth terminal group as a reference, together with the content of FIG. 9. Here, a periodic error (PeriodicError) occurs, which results from the accumulation of one cycle of the difference values (Diff(G_{g}, G_{g+1})) between the terminal groups.

The periodic error is shown below by Expression 4. In other words, the periodic error is represented by the sum of the shift amount of the final terminal group and the difference between the final terminal group and the first terminal group. In Expression 3, Diff(G_{gmax}, G₁) represents the difference value between the (gₘₐₓ)-th terminal group and the first terminal group, as shown in Expression 4.

$$\begin{matrix} Expression 3 & \\ periodicError = Shifttime ( {G}_{g m ax} ) + Diff ( {G}_{g ma x} , {G}_{1} ) & ( 3 ) \\ Expression 4 & \\ Diff ( {G}_{g m ax} , {G}_{1} ) = \frac{1}{{n}_{ma x}} {\sum }_{n = 1}^{{n}_{ma x}} ( CALDA ( {G}_{1} , n ) - CALDA ( {G}_{gm ax} , n ) ) & ( 4 )\end{matrix}$$

The periodic error may be calculated by the inter-group adjusting section 58, for example. First, the inter-group adjusting section 58 calculates, for each of the terminal groups from the first terminal group to the next to last terminal group, the difference value between the delay amount setting value set by the corresponding common setting section when the reference phases in the terminal group were adjusted and the delay amount setting value set by the corresponding common setting section when the reference phases in the next terminal group were adjusted.

Next, the inter-group adjusting section 58 calculates, for the final terminal group, the difference value between the delay amount setting value set by the corresponding common setting section when the reference phases in the final terminal group were adjusted and the delay amount setting value set by the corresponding common setting section when the reference phases in the first terminal group were adjusted. The inter-group adjusting section 58 calculates the periodic error to be the average of the difference values of each terminal group from the first terminal group to the last terminal group.

When the periodic error is greater than a predetermined value, for example, the inter-group adjusting section 58 preferably adjusts the reference phase by scattering the periodic error among the terminal groups. For example, the inter-group adjusting section 58 may shift the delay amount setting value for each I/O section 30 in the g-th terminal group by a correction shift amount (CorrShiftTime) calculated according to Expression 5 shown below. In Expression 5, AverageTime represents the average of the shift amounts of the terminal groups, as shown in Expression 6.

$$\begin{matrix} Expression 5 & \\ CorrShiftTime ( {G}_{g} ) = AverageTime - ShiftTime ( {G}_{g} ) + \frac{g - 1}{{g}_{ma x}} periodicError & ( 5 ) \\ Expression 6 & \\ AverageTime = \frac{1}{{g}_{ma x}} {\sum }_{g = 1}^{{g}_{m ax}} ShiftTime ( {G}_{g} ) & ( 6 )\end{matrix}$$

In other words, the inter-group adjusting section 58 shifts the delay amount setting value for each I/O section 30 in the g-th terminal group by an amount obtained by subtracting, from the average shift amount (AverageTime) of the terminal groups, the sum of the shift amount (ShiftTime(G_{g})) calculated for the g-th terminal group and the periodic error component (((g−1)/gₘₐₓ)×PeriodicError) scattered in the g-th terminal group. The periodic error component scattered in the g-th terminal group is the product of the periodic error (PeriodicError) and ((g−1)/gₘₐₓ), which is the ratio of g−1 to the total number (gₘₐₓ) of terminal groups.

In the example of FIG. 10, the difference value (Diff(G₄, G₁)) between the fourth terminal group and the first terminal group is 3.4 ns. Accordingly, in this case, the periodic error is 0.4 ns. Furthermore, the average shift amount (AverageTime) of the terminal groups is −1.0 ns.

Accordingly, in this case, the correction shift amount (CorrShiftTime(G₁)) for the first terminal group, the correction shift amount (CorrShiftTime(G₂)) for the second terminal group, the correction shift amount (CorrShiftTime(G₃)) for the third terminal group, and the correction shift amount (CorrShiftTime(G₄)) for the fourth terminal group are the values shown below.

CorrShiftTime(G₁)=−1.0 ns−0.0 ns+ 0/4(0.4 ns)=−1.0 ns

CorrShiftTime(G₂)=−1.0 ns−(−5.0 ns)+¼(0.4 ns)=4.1 ns

CorrShiftTime(G₃)=−1.0 ns−4.0 ns+ 2/4(0.4 ns)=−4.8 ns

CorrShiftTime(G₄)=−1.0 ns−(−3.0 ns)+¾(0.4 ns)=2.3 ns

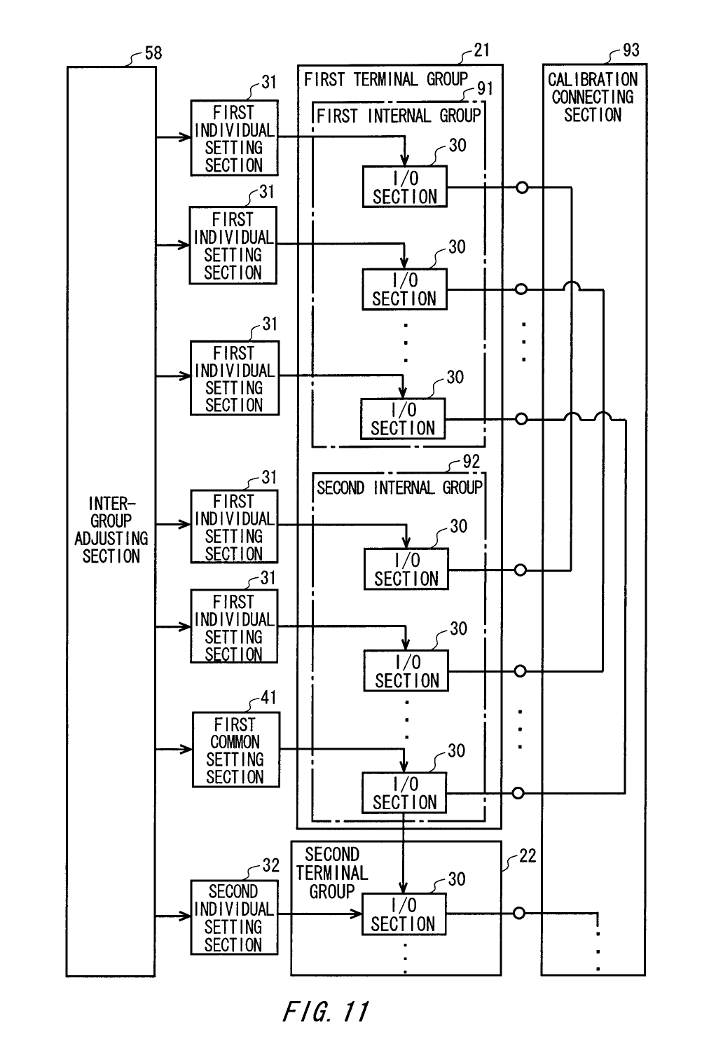

FIG. 11 shows an exemplary connection for a different process performed in step S12. In step S12, the intra-group adjusting section 56 may perform the following process, instead of the process described in FIG. 7, on each terminal group. In this example, there is a first terminal group 21, a second terminal group 22, and a third terminal group 23.

The I/O sections 30 in each terminal group are divided among a plurality of internal groups, which are the first internal group 91 and the second internal group 92 in the present embodiment. First, a calibration connecting section 93 is mounted on the test apparatus 10 to create a short between each I/O section 30 in the first internal group 91 and a corresponding I/O section 30 in the second internal group 92. In this way, each I/O section 30 in the first internal group 91 is connected to a corresponding I/O section 30 in the second internal group 92.

Next, for each pair of an I/O section 30 in the first internal group 91 and an I/O section 30 in the second internal group 92 connected to each other, the inter-group adjusting section 58 calculates the difference between the reference phases thereof. The inter-group adjusting section 58 then calculates the average difference of the reference phases between each of the pairs.

Next, the inter-group adjusting section 58 shifts the delay amount setting values for the I/O sections 30 in the second internal group 92 relative to the delay amount setting values for the I/O sections 30 in the first internal group 91, by an amount equal to the calculated average. In this way, the inter-group adjusting section 58 can cause the reference phases of the I/O sections 30 in the second internal group 92 to draw near and match the reference phases of the I/O sections 30 in the first internal group 91.

By performing this process at step S12, the test apparatus 10 can efficiently adjust the reference phases even when the test apparatus 10 is a large system having many terminals. When the process of step S12 is applied, the function and configuration of the test apparatus 10, as well as the processes other than step S12, i.e. steps S11 and S13, may be the same as described in FIGS. 1 to 10.

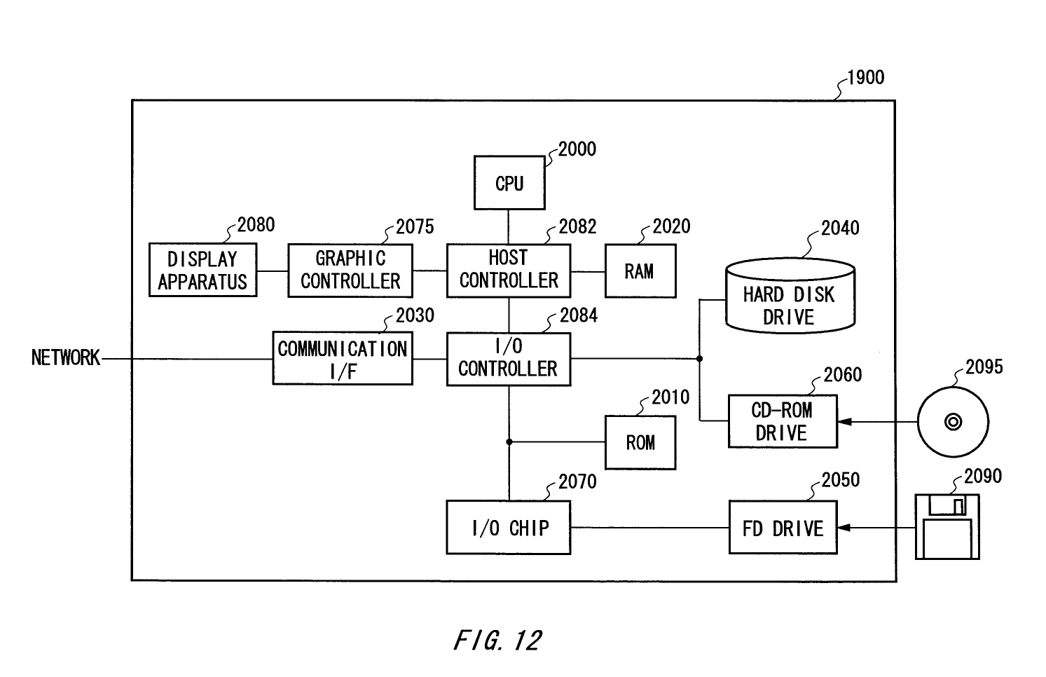

FIG. 12 shows an example of a hardware configuration of a computer 1900 according to the present embodiment. The computer 1900 according to the present embodiment is provided with a CPU peripheral including a CPU 2000, a RAM 2020, a graphic controller 2075, and a display apparatus 2080, all of which are connected to each other by a host controller 2082; an I/O section including a communication interface 2030, a hard disk drive 2040, and a CD-ROM drive 2060, all of which are connected to the host controller 2082 by an I/O controller 2084; and a legacy I/O section including a ROM 2010, a flexible disk drive 2050, and an I/O chip 2070, all of which are connected to the I/O controller 2084.

The host controller 2082 is connected to the RAM 2020 and is also connected to the CPU 2000 and graphic controller 2075 accessing the RAM 2020 at a high transfer rate. The CPU 2000 operates to control each section based on programs stored in the ROM 2010 and the RAM 2020. The graphic controller 2075 acquires image data generated by the CPU 2000 or the like on a frame buffer disposed inside the RAM 2020 and displays the image data in the display apparatus 2080. In addition, the graphic controller 2075 may internally include the frame buffer storing the image data generated by the CPU 2000 or the like.

The I/O controller 2084 connects the communication interface 2030 serving as a relatively high speed I/O apparatus, and the hard disk drive 2040, and the CD-ROM drive 2060 to the host controller 2082. The communication interface 2030 communicates with other apparatuses via a network. The hard disk drive 2040 stores the programs and data used by the CPU 2000 housed in the computer 1900. The CD-ROM drive 2060 reads the programs and data from a CD-ROM 2095 and provides the read information to the hard disk drive 2040 via the RAM 2020.

Furthermore, the I/O controller 2084 is connected to the ROM 2010, and is also connected to the flexible disk drive 2050 and the I/O chip 2070 serving as a relatively high speed I/O apparatus. The ROM 2010 stores a boot program performed when the computer 1900 starts up, a program relying on the hardware of the computer 1900, and the like. The flexible disk drive 2050 reads programs or data from a flexible disk 2090 and supplies the read information to the hard disk drive 2040 via the RAM 2020. The I/O chip 2070 connects the flexible disk drive 2050 to the I/O controller 2084 along with each of the I/O apparatuses via, a parallel port, a serial port, a keyboard port, a mouse port, or the like.

The programs provided to the hard disk drive 2040 via the RAM 2020 are stored in a storage medium, such as the flexible disk 2090, the CD-ROM 2095, or an IC card, and provided by a user. The programs are read from storage medium, installed in the hard disk drive 2040 inside the computer 1900 via the RAM 2020, and performed by the CPU 2000.

The programs installed in the computer 1900 to make the computer 1900 function as the test apparatus 10 are provided with an a terminal adjusting module, an intra-group adjusting module, and an inter-group adjusting module. These programs and modules prompt the CPU 2000 or the like to make the computer 1900 function as the terminal adjusting section 54, the intra-group adjusting section 56, and the inter-group adjusting section 58, respectively.

The information processes recorded in these programs are read by the computer 1900 to cause the computer 1900 to function as software and hardware described above, which are exemplified by the specific sections of the terminal adjusting section 54, the intra-group adjusting section 56, and the inter-group adjusting section 58. With these specific sections, a unique test apparatus 10 suitable for an intended use can be configured to function by realizing the calculations or computations appropriate for the intended use of the computer 1900 of the present embodiment.

For example, if there is communication between the computer 1900 and an external apparatus or the like, the CPU 2000 performs the communication program loaded in the RAM 2020, and provides the communication interface 2030 with communication processing instructions based on the content of the process recorded in the communication program. The communication interface 2030 is controlled by the CPU 2000 to read the transmission data stored in the transmission buffer area or the like on the storage apparatus, such as the RAM 2020, the hard disk drive 2040, the flexible disk 2090, or the CD-ROM 2095, and send this transmission data to the network, and to write data received from the network onto a reception buffer area on the storage apparatus. In this way, the communication interface 2030 may transmit data to and from the storage apparatus through DMA (Direct Memory Access). As another possibility, the CPU 2000 may transmit the data by reading the data from the storage apparatus or communication interface 2030 that are the origins of the transmitted data, and writing the data onto the communication interface 2030 or the storage apparatus that are the transmission destinations.

The CPU 2000 may perform various processes on the data in the RAM 2020 by reading into the RAM 2020, through DMA transmission or the like, all or a necessary portion of the database or files stored in the external apparatus such as the hard disk drive 2040, the CD-ROM drive 2060, the CD-ROM 2095, the flexible disk drive 2050, or the flexible disk 2090. The CPU 2000 writes the processed data back to the external apparatus through DMA transmission or the like. In this process, the RAM 2020 is considered to be a section that temporarily stores the content of the external storage apparatus, and therefore the RAM 2020, the external apparatus, and the like in the present embodiment are referred to as a memory, a storage section, and a storage apparatus. The variety of information in the present embodiment, such as the variety of programs, data, tables, databases, and the like are stored on the storage apparatus to become the target of the information processing. The CPU 2000 can hold a portion of the RAM 2020 in a cache memory and read from or write to the cache memory. With such a configuration as well, the cache memory serves part of the function of the RAM 2020, and therefore the cache memory is also included with the RAM 2020, the memory, and/or the storage apparatus in the present invention, except when a distinction is made.

The CPU 2000 executes the various processes such as the computation, information processing, condition judgment, searching for/replacing information, and the like included in the present embodiment for the data read from the RAM 2020, as designated by the command sequence of the program, and writes the result back onto the RAM 2020. For example, when performing condition judgment, the CPU 2000 judges whether a variable of any type shown in the present embodiment fulfills a condition of being greater than, less than, no greater than, no less than, or equal to another variable or constant. If the condition is fulfilled, or unfulfilled, depending on the circumstances, the CPU 2000 branches into a different command sequence or acquires a subroutine.

The CPU 2000 can search for information stored in a file in the storage apparatus, the database, and the like. For example, if a plurality of entries associated respectively with a first type of value and a second type of value are stored in the storage apparatus, the CPU 2000 can search for entries fulfilling a condition designated by the first type of value from among the plurality of entries stored in the storage apparatus. The CPU 2000 can then obtain the second type of value associated with the first type of value fulfilling the prescribed condition by reading the second type of value stored at the same entry.

The programs and modules shown above may also be stored in an external storage medium. The flexible disk 2090, the CD-ROM 2095, an optical storage medium such as a DVD or CD, a magneto-optical storage medium, a tape medium, a semiconductor memory such as an IC card, or the like can be used as the storage medium. Furthermore, a storage apparatus such as a hard disk or RAM that is provided with a server system connected to the Internet or a specialized communication network may be used to provide the programs to the computer 1900 via the network.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A test apparatus that tests a device under test, comprising:
a first terminal group and a second terminal group including a plurality of drivers that output signals to the device under test;
a first common setting section that sets a common delay amount for the signals output from one driver in the first terminal group and one driver in the second terminal group; and
an inter-group adjusting section that causes reference phases of the signals output from the drivers in the first terminal group and reference phases of the signals output from the drivers in the second terminal group to draw near each other, based on a delay amount setting value set by the first common setting section when the reference phases in the first terminal group were adjusted and a delay amount setting value set by the first common setting section when the reference phases in the second terminal group were adjusted.

2. The test apparatus according to claim 1, wherein
the first common setting section sets a delay amount of a delay circuit that delays a signal supplied in common to the one driver in the first terminal group and the one driver in the second terminal group.

3. The test apparatus according to claim 2, further comprising:
a plurality of first individual setting sections that respectively set delay amounts of signals output by the drivers in the first terminal group other than the one driver in the first terminal group;
a plurality of second individual setting sections that respectively set delay amounts of signals output by the drivers in the second terminal group other than the one driver in the second terminal group; and
an intra-group adjusting section that adjusts the delay amounts set for the first common setting section and the first individual setting sections such that the reference phases of the signals output by the drivers in the first terminal group draw near each other, and adjusts the delay amounts set for the first common setting section and the second individual setting sections such that the reference phases of the signals output by the drivers in the second terminal group draw near each other.

4. The test apparatus according to claim 3, wherein
the inter-group adjusting section shifts each of the delay amounts set by the second individual setting sections by a first shift amount corresponding to a difference value between the delay amount setting value set by the first common setting section when the reference phases in the first terminal group were adjusted and the delay amount setting value set by the first common setting section when the reference phases in the second terminal group were adjusted.

5. The test apparatus according to claim 4, further comprising a plurality of the first common setting sections, wherein
the inter-group adjusting section sets the first shift amount to be an average of the difference values of the plurality of first common setting sections.

6. The test apparatus according to claim 5, further comprising:
a third terminal group that includes a plurality of drivers that output signals to the device under test;
a second common setting section that sets a common delay amount for the signals output from one driver in the second terminal group and one driver in the third terminal group; and
a plurality of third individual setting sections that respectively set delay amounts of signals output by the drivers in the third terminal group other than the one driver in the third terminal group, wherein
the intra-group adjusting section adjusts the delay amounts set for the second common setting section and the third individual setting sections such that the reference phases of the signals output by the drivers in the third terminal group draw near each other,
the inter-group adjusting section shifts each of the delay amount setting values set by the first common setting section and the second individual setting sections by the first shift amount, and
the inter-group adjusting section shifts each of the delay amounts set by the third individual setting sections by the sum of the first shift amount and a second shift amount corresponding to a difference value between the delay amount setting value set by the second common setting section when the reference phases in the second terminal group were adjusted and the delay amount setting value set by the second common setting section when the reference phases in the third terminal group were adjusted.

7. The test apparatus according to claim 6, comprising:
a plurality of the terminal groups having a plurality of drivers that output signals to the device under test; and
a plurality of the common setting sections that correspond respectively to the plurality of terminal groups and that each set a common delay amount for signals output from one driver in the corresponding terminal group and one driver in the terminal group that is subsequent to the corresponding terminal group, wherein
for each terminal group from the first terminal group to the next to last terminal group, the inter-group adjusting section calculates a difference value between the delay amount setting value set by the corresponding common setting section when the reference phases were adjusted and the delay amount setting value set by the corresponding common setting section when the reference phases in the subsequent terminal group were adjusted,
for the last terminal group, the inter-group adjusting section calculates a difference value between the delay amount setting value set by the corresponding common setting section when the reference phases were adjusted and the delay amount setting value set by the corresponding common setting section when the reference phases in the first terminal group were adjusted,
the inter-group adjusting section calculates a periodic error to be an average of each of the difference values calculated for the terminal groups from the first terminal group to the last terminal group, and
for each terminal group, the inter-group adjusting section shifts the delay amount setting values of the signals output by the drivers in the terminal group by a shift amount corresponding to the difference value and by a correction shift amount based on a component of the periodic error scattered in the terminal group.

8. The test apparatus according to claim 1, wherein
the test apparatus tests a plurality of the devices under test in parallel, and
the first common setting section is provided to correspond to a plurality of drivers for supplying the same signal to the devices under test.

9. The test apparatus according to claim 3, wherein
the first terminal group and the second terminal group each include a first internal group and a second internal group that each have a plurality of I/O sections, each I/O section containing a driver for outputting a signal to a terminal of the device under test and a comparator for receiving a signal from the terminal of the device under test, and
with each I/O section in the first internal group connected to an I/O section in the second internal group, the intra-group adjusting section calculates a difference in reference phases between each pair of an I/O section in the first internal group and an I/O section in the second internal group that are connected to each other, and causes the reference phases of each pair to draw near each other based on the calculated reference phase difference.

10. A calibration method for a test apparatus that tests a device under test, wherein the test apparatus includes:
a first terminal group and a second terminal group including a plurality of drivers that output signals to the device under test; and
a first common setting section that sets a common delay amount for the signals output from one driver in the first terminal group and one driver in the second terminal group, the method comprising:
causing reference phases of the signals output from the drivers in the first terminal group and reference phases of the signals output from the drivers in the second terminal group to draw near each other, based on a delay amount setting value set by the first common setting section when the reference phases in the first terminal group were adjusted and a delay amount setting value set by the first common setting section when the reference phases in the second terminal group were adjusted.

11. A recording medium storing thereon a program causing a computer to function as an apparatus that calibrates a test apparatus for testing a device under test, wherein
the test apparatus includes:
a first terminal group and a second terminal group including a plurality of drivers that output signals to the device under test; and
a first common setting section that sets a common delay amount for the signals output from one driver in the first terminal group and one driver in the second terminal group, and
the program causes the computer to function as an inter-group adjusting section causing reference phases of the signals output from the drivers in the first terminal group and reference phases of the signals output from the drivers in the second terminal group to draw near each other, based on a delay amount setting value set by the first common setting section when the reference phases in the first terminal group were adjusted and a delay amount setting value set by the first common setting section when the reference phases in the second terminal group were adjusted.
